(19) United States
(12) Patent Application Publication
(10) Pub. No.: US 2026/0073082 A1
(43) Pub. Date: Mar. 12, 2026

(54) METHOD AND SYSTEM FOR EVALUATING HARDNESS OF CERAMIC MATERIAL BY USING COMPUTATIONAL SIMULATION

(71) Applicant: Foundation of Soongsil University-Industry Cooperation, Seoul (KR)

(72) Inventors: Jiwoong KIM, Seoul (KR); Sooah KYUNG, Seoul (KR); Hyokyeong KIM, Seoul (KR); Jinyong LEE, Seoul (KR); Jaewon CHOI, Bucheon-si (KR)

(21) Appl. No.: 19/268,256

(22) Filed: Jul. 14, 2025

(30) Foreign Application Priority Data
Sep. 12, 2024 (KR) 10-2024-0124856

(51) Int. Cl. G06F 30/10

(52) U.S. Cl. CPC G06F 30/10

(57) ABSTRACT

Provided is a method of evaluating hardness of a ceramic material by using computational simulation, including a first operation in which a crystal structure model reflecting a kind and amount of an element to be added to a material, a second operation in which a stabilized structure, in which the crystal structure model has the lowest energy, of the crystal structure model is selected, a third operation in which a plurality of modified models having a series of strains with respect to the stabilized structure are generated, a fourth operation in which elastic moduli about respective modified models are calculated from the strains and energy, and a fifth operation in which a finite element analysis (FEA) program simulating an indentation test on a crystal structure is modeled, and the elastic moduli are substituted into the FEA program to extract physical property data about the crystal structure model.

### CROSS-REFERENCE TO RELATED APPLICATION

This application is based on and claims priority under 35 U.S.C. § 119 to Korean Patent Application No. 10-2024-0124856, filed on Sep. 12, 2024, in the Korean Intellectual Property Office, the disclosure of which is incorporated by reference herein in its entirety.

### BACKGROUND

### 1. Field

The present disclosure relates to a method and system for evaluating hardness of a ceramic material based on a carbide by using computational simulation, through first-principles calculations and finite element analysis.

### 2. Description of the Related Art

According to recent technical advancements, a novel material having highly-advanced functions is required, and thus, research and development related to novel materials are actively performed. Among them, ceramics are highlighted as an important industrial material in a field where metal materials or polymer materials are difficult to apply.

Ceramics, which are novel materials with mechanically excellent characteristics, are widely used in various fields, e.g., mechanical engineering, electronics engineering, aerospace engineering, biomaterials, etc., and evaluation on the characteristics of ceramic materials are required as a priority in order to develop and apply the ceramic material suitable for each technical field.

In particular, an indentation test is widely used in order to measure hardness that is a main mechanical characteristic of a carbide-based ceramic material. The indentation test is relatively simple, and with the advancement of equipment, has become a unique scientific and engineering research tool for various material systems from a macro level to a nano-level.

However, in order to research various material systems and to apply an indentation test method as a precise and quantitative method beyond laboratories, a depth modeling and consideration through robust analysis of experimental results are required, and in order to physically perform the indentation test, there is a limitation that the manufacturing of the specimen has to be performed with priority, and thus, time and cost limitations occur.

### SUMMARY

To address the above issues, the present disclosure provides a method and system for evaluating hardness of a ceramic material by using a computational simulation, capable of evaluating mechanical characteristics of a material based on a computer design, e.g., first-principles calculations and finite element analysis (FEA) without manufacturing an actual specimen.

According to an embodiment of the present disclosure, a method of evaluating hardness of a ceramic material by using computational simulation, includes a first operation in which a crystal structure model reflecting a kind and amount of an element to be added to a material, a second operation in which a stabilized structure, in which the crystal structure model has the lowest energy, of the crystal structure model is selected, a third operation in which a plurality of modified models having a series of strains with respect to the stabilized structure are generated, a fourth operation in which elastic moduli about respective modified models are calculated from the strains and energy, and a fifth operation in which a finite element analysis (FEA) program simulating an indentation test on a crystal structure is modeled, and the elastic moduli are substituted into the FEA program to extract physical property data about the crystal structure model.

In an embodiment, the material may be a ceramic material including a carbide.

In an embodiment, the method may further include determining a synthesis possibility of the crystal structure model by calculating formation energy of the crystal structure model.

In an embodiment, the method may further include determining a synthesis possibility of the crystal structure model by comparing the crystal structure model with competing phases.

In an embodiment, the elastic modulus may include a bulk modulus and a shear modulus, or Young's modulus of the material.

In an embodiment, the physical property data may include hardness of the material.

According to another embodiment of the present disclosure, a system for evaluating hardness of a ceramic material by using computational simulation, includes a memory storing a program configured to calculate an elastic modulus of a material and extract physical property data of the material from the elastic modulus, and a processor configured to generate a crystal structure model of the material, calculate the elastic modulus of the crystal structure model through the program stored in the memory, generate the physical property data, and determine suitability of the material based on the elastic modulus and the physical property data.

Other aspects, features and advantages other than those described above will become apparent from the following detailed description of the drawings, claims and disclosure.

### BRIEF DESCRIPTION OF THE DRAWINGS

The above and other aspects, features, and advantages of certain embodiments of the disclosure will be more apparent from the following description taken in conjunction with the accompanying drawings in which:

FIG. 1 is a flowchart schematically illustrating a method of evaluating hardness of a ceramic material by using a computational simulation, according to an embodiment of the present disclosure;

FIG. 2 is a diagram showing an example of a crystal structure model according to the present disclosure;

FIG. 3 schematically shows a graph for comparing free energy of a crystal structure model according to the present disclosure;

FIG. 4 shows a graph for comparing formation energy of a crystal structure model according to the present disclosure;

FIG. 5 is a diagram showing an example of competing phases with respect to a crystal structure model according to the present disclosure;

FIG. 6 is a diagram showing an example of modified models from a crystal structure model according to the present disclosure;

FIG. 7 is a diagram showing an example of a compliance matrix with respect to a crystal structure model according to the present disclosure;

FIG. 8 is a diagram schematically showing an elastic constant required according to a crystal structure;

FIG. 9 is a diagram showing an example of an element mesh for finite element analysis of a crystal structure model according to the present disclosure;

FIG. 10 is a diagram showing a visualization of a hardness evaluation result of a material according to finite element analysis; and

FIG. 11 is a conceptual diagram schematically showing a system for evaluating hardness of a ceramic material by using computational simulation, according to the present disclosure.

### DETAILED DESCRIPTION

As the present disclosure allows for various changes and numerous embodiments, particular embodiments will be illustrated in the drawings and described in detail in the written description. The attached drawings for illustrating one or more embodiments are referred to in order to gain a sufficient understanding, the merits thereof, and the objectives accomplished by the implementation. However, the embodiments may have different forms and should not be construed as being limited to the descriptions set forth herein.

The embodiments will be described below in more detail with reference to the accompanying drawings. Those components that are the same or are in correspondence are rendered the same reference numeral regardless of the figure number, and redundant explanations are omitted.

While such terms as “first,” “second,” etc., may be used to describe various components, such components are not limited to the above terms. The above terms are used only to distinguish one component from another.

An expression used in the singular encompasses the expression of the plural, unless it has a clearly different meaning in the context.

In the present specification, it is to be understood that the terms “including,” “having,” and “comprising” are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

Sizes of components in the drawings may be exaggerated for convenience of explanation. In other words, since sizes and thicknesses of components in the drawings are arbitrarily illustrated for convenience of explanation, the following embodiments are not limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment is implemented differently, a specific process order may be performed differently from the described order. For example, two consecutively described processes may be performed substantially at the same time or performed in an order opposite to the described order.

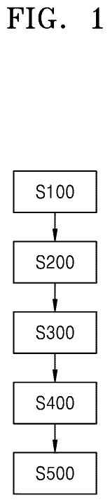

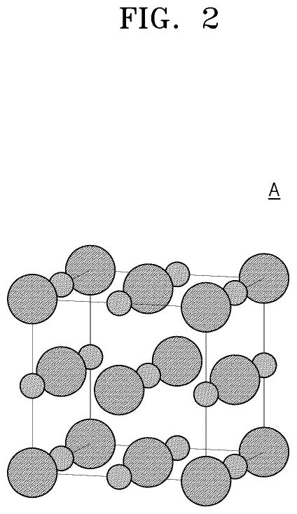

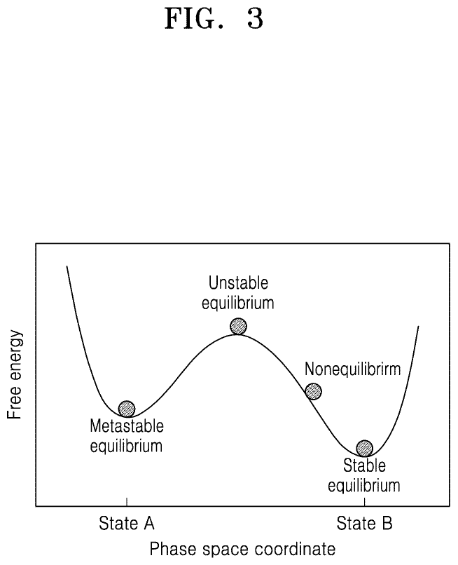

FIG. 1 is a flowchart schematically illustrating a method of evaluating hardness of a ceramic material by using a computational simulation, according to an embodiment of the present disclosure. Also, FIG. 2 is a diagram showing an example of a crystal structure model according to the present disclosure, and FIG. 3 schematically shows a graph for comparing free energy of the crystal structure model according to the present disclosure.

Referring to FIG. 1, according to an embodiment of the present disclosure, a method of evaluating hardness of a ceramic material by using computational simulation may include first operation (S100) in which a crystal structure model A reflecting a kind and amount of an element to be added to a carbide-based ceramic material, second operation (S200) in which a stabilized structure of the crystal structure model, in which the crystal structure model A having a minimum energy, is selected, third operation (S300) in which a plurality of modified models having a series of strains with respect to the stabilized structure are generated, fourth operation (S400) in which an elastic constant and an elastic modulus with respect to each modified model are calculated from the strain and energy, and fifth operation (S500) in which a finite element analysis (FEA) program simulating an indentation test for the crystal structure is modeled, and physical property data of the crystal structure model is extracted by substituting the elastic modulus in the FEA program.

Also, in an embodiment, the material may include a ceramic material including a carbide.

Ceramics may have excellent mechanical properties such as hardness, elastic modulus, etc. and different thermal, chemical, and genetic properties due to a strong chemical bond applied between constituent atoms or ions. Also, because ceramics are mostly manufactured and used as polycrystals, physical and mechanical properties of the material may be largely affected by states such as crystalline particles that are unique microstructures, interfaces between crystals, defects, pores, etc. In particular, a carbide-based ceramic may have excellent thermal and mechanical properties and chemical safety due to a strong covalent bond.

Therefore, in an embodiment, in first operation (S100), a crystal structure model A that is a target of physical property evaluation may be generated in consideration of a kind and amount of an element to be added to the material, for evaluating the physical properties of the material. For example, FIG. 2 shows modeling a carbide having a rock salt structure into the crystal structure model (A), but the present disclosure is not limited to the example.

Second operation (S200) for selecting a stabilized structure of the crystal structure model A, in which the crystal structure model A has the lowest energy, is to design a new material of a stabilized structure by calculating the lowest energy of a molecule.

The material has a total energy of atoms, molecules, or clusters according to physical factors such as a structure, a bonding length, and a bonding angle of the crystals in the material. Here, the lowest energy of the material denotes an energy level when the material is in the most stabilized condition. The total energy of the crystal structure model A may be calculated through various calculation methods, e.g., a density functional theory (DFT) calculation, a molecular dynamics simulation, etc.

In detail, the DFT is used to quantify and analyze movements of the electrons and to predict an electronic structure of a solid or a molecule. An electron density function, which is a key concept of the DFT, denotes a probability that electrons are distributed in a specific space, and as such, movement and interactions of the electrons may be modeled.

Referring to FIG. 3, the crystal structure model A may exist in a stable equilibrium state (State B) having the lowest energy level, a metastable equilibrium state (State A) having relatively low energy level, an unstable equilibrium state having high energy level, and a nonequilibrium state between the unstable equilibrium state and the stable equilibrium. By adopting the crystal structure model A having the low energy like in the stable equilibrium state and the metastable equilibrium state from among those states, the most stabilized structure may be obtained.

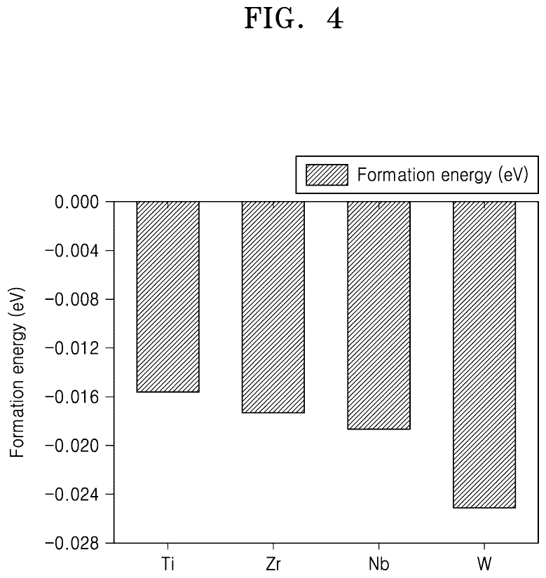

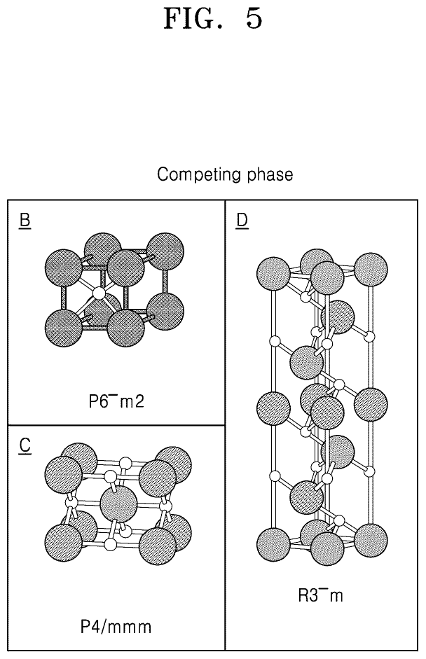

FIG. 4 is a graph for comparing formation energy of a crystal structure model according to the present disclosure, and FIG. 5 is a diagram showing examples of competing phases with respect to the crystal structure model of the present disclosure.

In an embodiment, an operation for determining a synthesis possibility of the crystal structure model A by calculating a formation energy (E_{f}) of the crystal structure model A may be further provided.

The formation energy (E_{f}) may represent a variation in the energy consumed or discharged when a compound is generated by bonding component elements that are in the most stabilized forms in standard states. This may be utilized to evaluate stability and possibility of forming a compound at a certain temperature and pressure.

The formation energy (E_{f}) of the crystal structure model A may be expressed by equation 1 below.

$${E}_{f} = {E}_{d o p e d} - {E}_{c o m p}$$

Here, E_{doped} is the energy of the hetero-element doping phase and E_{comp} denotes the energy of a competing phase.

When the formation energy is negative (E_{f}<0), the compound is stabilized as compared with the elements that are constituents thereof, and it may be determined that the compound is more stabilized as the formation energy decreases. For example, referring to FIG. 4, it may be determined that a stabilized compound may be formed when being substituted with tungsten (W), niobium (Nb), zirconium (Zr), and titanium (Ti) in the stated order.

Also, in an embodiment, the method of evaluating hardness of the ceramic material using the computational simulation according to the present disclosure may further include determining the synthesis possibility of the crystal structure model A by comparing with the competing phase of the crystal structure model A.

Referring to FIG. 5, the competing phase denotes a structural variation with different arrangement of atoms from the crystal structure model and a composition deformation including different composition. The competing phases have various physical properties and chemical stabilities, which may be compared with each other to predict the stability of the material.

In other words, the possibility of synthetizing single-phase carbides may be predicted through the process of calculating and comparing the stabilities of the single-phase carbides through the calculation of the formation energy (E_{f}) and comparison with the competing phase.

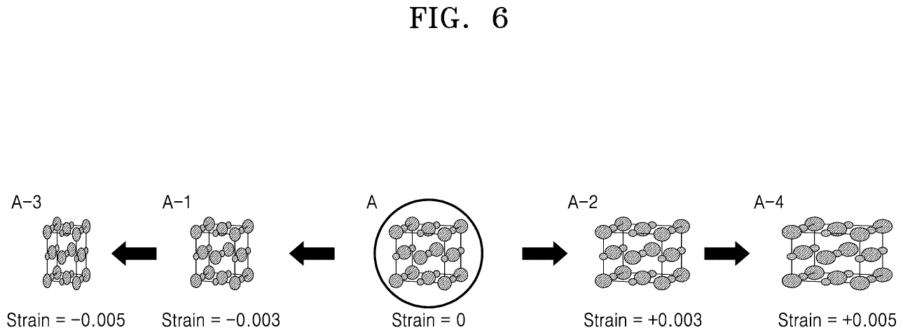

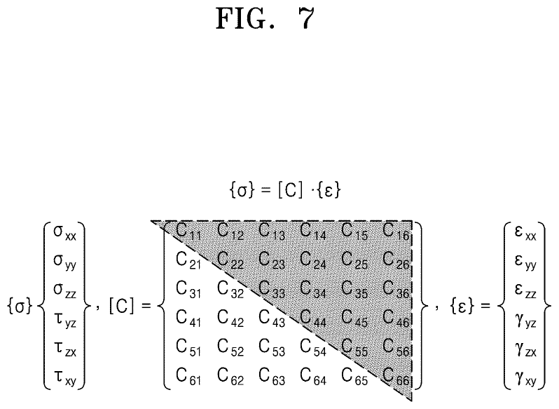

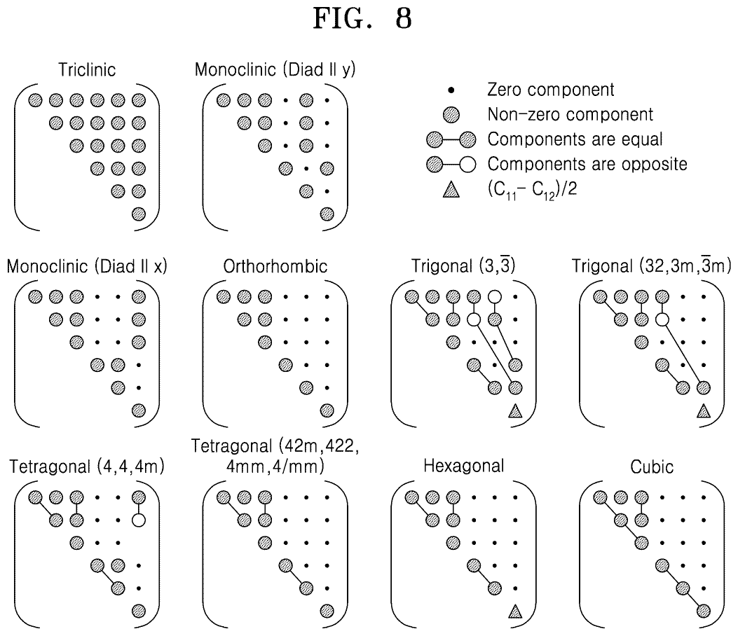

FIG. 6 is a diagram showing an example of modified models from the crystal structure model according to the present disclosure. Also, FIG. 7 shows an example of a compliance matrix with respect to the crystal structure model according to the present disclosure, and FIG. 8 is diagram schematically showing elastic constants required according to the crystal structure.

In third operation (S300), a plurality of modified models A-1, A-2, A-3, and A-4 having a series of strains may be generated to extract elastic constants and elastic modulus for deriving mechanical characteristics with respect to the stabilized structure of the crystal structure model A.

For example, referring to FIG. 6, the modified models A-1, A-2, A-3, and A-4 having strains of ±0.003 and ±0.005 with respect to the stabilized structure of the crystal structure model A.

Here, the elastic constants and elastic modulus for analyzing the mechanical characteristics of the material without carrying out actual experiments may be calculated by a first-principles calculation method. For example, energy, structure, and reactive thermodynamic property of the molecules may be predicted.

In an embodiment, the elastic modulus may include a bulk modulus, a shear modulus, or Young's modulus and Poisson's ratio of the material.

The elastic constants C₁₁, C₂₂, and C₄₄ may be important indicators representing characteristics such as stability, rigidity, brittleness, ductility, and elastic anisotropy of the material, as well as the mechanical behavior of the material.

Also, the bulk modulus may represent a resistance to an external pressure, and the shear modulus and the Young's modulus are both affected by the strength of the bonds forming the crystal structure model A, and may directly affect macroscopic mechanical properties.

Referring to FIG. 7, elastic constants C and compliances are calculated from the stress and strain, and may be represented as a compliance matrix.

In detail, the elastic constant may be expressed as σ/e when the elastic deformation e is proportional to the stress a with respect to the elastic deformation e.

In general, in the case of a crystal having different properties depending on the direction, components of a strain tensor are represented as eₓₓ, e_{yy}, e_{zz}, e_{yz}, e_{zx}, e_{xy} and components of a stress tensor are represented as ρₓₓ, ρ_{yy}, ρ_{zz}, ρ_{yz}, ρ_{zx}, ρ_{xy}, equation 2 below may be expressed by Hook's law.

$${ρ}_{x x} = {C}_{11} {e}_{x x} + {C}_{12} {e}_{y y} + {C}_{13} {e}_{zz} + {C}_{14} {e}_{y z} + {C}_{15} {e}_{z x} + {C}_{16} {e}_{x y}$$

Here, a constant Cⱼₖ(j, k=1, 2, . . . , 6) is referred to as an elastic constant.

Here, when a strain energy function W (or elastic energy) is present, fifteen relational expressions of Cᵢₖ=Cₖₜ (i, k=1, 2, . . . , 6) are established, and in this case, values of the elastic constants C in the matrix have symmetry, and thus, the number of independent elastic constants may be calculated as 21.

When the crystal has symmetric axes and symmetric surfaces, by setting appropriate coordinate axes (x, y, z) based on the crystal, there are a few additional relational equations between Cᵢₖ again, and the number of independent elastic modulus decreases. For example, there are thirteen elastic moduli in a monoclinic crystal system (having one symmetrical surface) and three elastic moduli in an equiaxed crystal system.

Referring to FIG. 8, the elastic constants C that may be offset may vary depending on the crystal structure of the material.

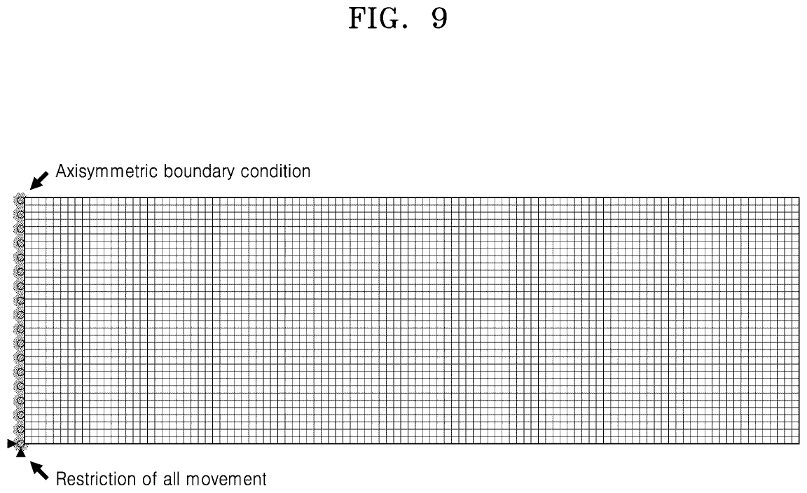

FIG. 9 is a diagram showing an example of an element mesh for the FEA of the crystal structure model according to the present disclosure.

In fifth operation (S500), physical property data with respect to the crystal structure model A may be extracted through the FEA by using the elastic modulus. Here, a commercialized FEA program may be used for the FEA.

In an embodiment, the physical property data may include hardness of the material. In order to obtain the physical property data with respect to the hardness, an FEA program simulating an indentation test for the crystal structure may be modeled and the elastic modulus may be substituted therein.

The FEA is an engineering computational method used to predict and analyze behaviors of a complicated physical system or structure, and quantifies physical characteristics such as stress, deformation, heat transfer, etc. of the structure or mechanical components by combining a mathematical modeling and a computer simulation.

For the FEA, the crystal structure model A may be divided into the finite number of small elements so as to mathematically model the physical characteristics of each element. In general, the element has a shape of a point, a line, a surface, etc., and the characteristics of the entire material are predicted through the interaction between the elements. For example, as shown in FIG. 9, when performing a structural analysis in the FEA, a shape of an analysis target may be approximated and expressed as an element mesh of the model.

Also, for the FEA, boundary conditions may be set in order to define conditions at the boundary of the analysis target system. The boundary conditions may be assigned through the FEA program and may allow a load or a displacement to be applied to the model. Then, an equation of the entire system may be set based on a matrix representing the physical characteristics of each element. As such, the hardness, stress, deformation, heat transfer, etc. of the material may be quantitively calculated. Also, the constructed mathematical model may be solved by using a computer, and stress distribution, deformation aspects, heat transfer characteristics, etc. of the structure may be visualized and provided as an analysis result.

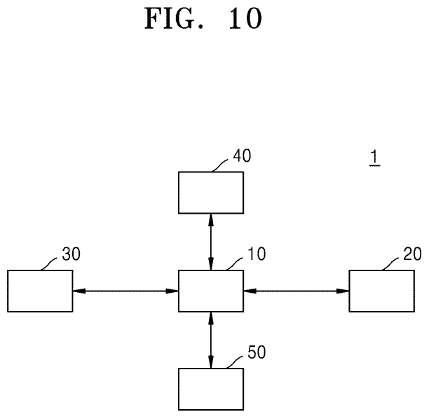

FIG. 10 is a diagram showing a visualization of hardness evaluation result for a material according to the finite element analysis.

Referring to FIG. 10, a first image at the uppermost part represents a state before starting hardness measurement, that is, before applying a load, through the FEA program simulating an indentation test. Also, a second image represents a state in which the indentation has been performed to a maximum load, and a last image at the lowermost part represents a state from which the load is removed.

According to the method of evaluating hardness of the ceramic material using computational simulation, stress variation according to the indentation test modeling performed via the FEA program may be numerically observed, and the result may be derived as visualized data as shown in FIG. 10 to easily identify the mechanical characteristics of the material.

In particular, in the visualized data, when the color changes from blue to red, it may represent that a degree of stress applied to the specimen increases. For example, in the first image, the specimen before applying the load is observed as blue color without generating stress, and in the specimen, to which the largest load is applied, of the second image, red color distribution is observed the most, and in the specimen from which the load is removed in the last image, partial red color distribution due to the residual stress may be observed.

As described above, according to the method of evaluating hardness of the ceramic material using the computational simulation of the present disclosure, mechanical characteristics, hardness value, etc. of the ceramic material such as various carbides may be predicted and an optimal composition may be easily derived.

Therefore, costs and time duration taken to perform experiments for developing new ceramic materials and production may be minimized.

Also, according to the present disclosure, the hardness of a sintered substance according to a density may be obtained according to the crystal structure model by utilizing the FEA, and thus, it may be possible to analyze and examine a cause of degradation in the physical property occurring in the experiment.

Therefore, issues of the related art may be addressed and the efficiency and reliability in designing and producing the new ceramic materials may be improved, thereby leading to the development of the new material field.

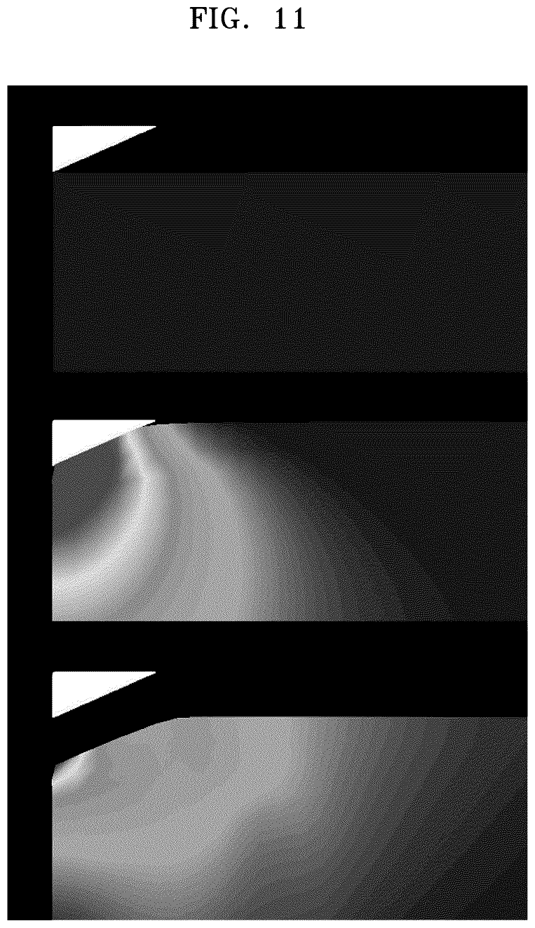

FIG. 11 is a conceptual diagram schematically showing a system 1 for evaluating hardness of a ceramic material by using computational simulation according to the present disclosure.

Referring to FIG. 11, the system 1 for evaluating hardness of the ceramic material by using the computational simulation according to an embodiment of the present disclosure may include a processor 10 and a memory 20. Also, the system 1 may further include a communicator 30, an input unit 40, and a display portion 50.

The memory 20 may store programs for calculating the elastic modulus of the material, and extracting physical property data of the material from the elastic modulus.

Here, the memory 20 may collectively refer to a non-volatile storage device for retaining the stored information without power supply, and a volatile storage device. For example, the memory 20 may include a NAND flash memory such as a compact flash (CF) card, a secure digital (SD) card, a memory stick, a solid-state drive (SSD), a micro-SD card, etc., a magnetic computer storage device such as a hard disk drive (HDD), etc., an optical disc drive such as CD-ROM, DVD-ROM, etc.

The processor 10 may execute software such as a program, etc. to control at least one another component (e.g., a hardware or software component) of the system 1, and perform various data processing or computations. In particular, the processor 10 generates the crystal structure model A of the material and physical property data stored in the memory 20, and may determine the suitability of the material based on the elastic modulus and the physical property data.

The method of evaluating physical property of a material according to the FEA according to an embodiment of the present disclosure may be implemented as a program (or application) and stored in a medium in order to be combined with a computer, that is, hardware and executed.

In order to allow the computer to read the program and execute the methods implemented with the program, the above-described program may include codes encoded in computer languages such as C, C++, JAVA, and machine language which can be read through a device interface of the computer by a processor (CPU) of the computer. This code may include a functional code related to a function or the like that defines functions required to execute the methods, and may include an execution procedure-related control code necessary for the processor of the computer to execute the functions in accordance with a predetermined procedure. Also, such a code may further include a memory reference related code as to which additional information or media required for the processor of the computer to execute the above-described functions should be referenced at any location (address) of the internal or external memory of the computer. In addition, when the processor of the computer needs to communicate with any other computer, server, etc., which are at remote locations, to perform the above-described functions, the code may further include a communication-related code as to how to communicate with which remote computer, server, etc., what information or media should be transmitted or received during communication, and the like.

The recording medium refers to a specific medium that semi-permanently stores data and may be read by an apparatus, rather than a medium, such as a register, a cache, or a buffer, which temporarily stores data. Specifically, the recording medium may include, but is not limited to, a ROM, a RAM, a CD-ROM, a magnetic tape, a floppy disk, an optical data storage device, and the like. That is, the program may be stored in various recording media on various servers to which the computer may access, or in various recording media on the user's computer. The medium may also be distributed over network coupled computer systems so that the computer readable code is stored in a distributive manner.

The communicator 30 transmits/receives data between inner and outer components of the system 1 for evaluating hardness of the ceramic material by using the computational simulation. The communicator 30 may include both a wired communication module and a wireless communication module. The wired communication module may be implemented as a power line communication device, a telephone line communication device, a cable home (Multimedia over Coax Alliance (MoCA)), an Ethernet module, an IEEE1294 module, a wired integrated home network, and an RS-485 controller. Also, the wireless communication module may be implemented as a module for supporting wireless LAN (WLAN), a Bluetooth module, an high data rate (HDR) wireless personal area network (WPAN) module, an ultra-wideband (UWB) module, a ZigBee module, an Impulse Radio module, a 60 GHz WPAN module, a Binary-CDMA module, a wireless universal serial bus (USB), and a wireless high-definition multimedia interface (HDMI), and the other modules for implementing a 5th generation (5G) communication, long term evolution-advanced (LTE-A), long term evolution (LTE), wireless fidelity (Wi-Fi), etc.

The input unit 40 generates input data corresponding to a user input into the system 1 for evaluating hardness of the ceramic material by using the computational simulation. The input unit 40 may include at least one input unit. The input unit 40 may include a keyboard, a keypad, a dome switch, a touch panel, a touch key, a mouse, a menu button, etc.

The display portion 50 displays display data according to the operation of the system 1 for evaluating hardness of the ceramic material by using the computational simulation. The display portion 50 may include a liquid crystal display (LCD), a light-emitting diode (LED) display, an organic light-emitting diode (OLED) display, a micro electro mechanical systems (MEMS) display, and an electronic paper display. The display portion 50 may be implemented as a touch screen by combining with the input unit 40.

The system 1 for evaluating hardness of the ceramic material by using the computational simulation according to the present disclosure may derive a material of a desired hardness through various condition changes, and after calculating the hardness, the modeling result of the indentation test may be provided as visualized and numerical data.

Also, the system 1 for evaluating hardness of the ceramic material by using the computational simulation collects the modeling results of the indentation test on the crystal structure model of a new material as a database, and automates the entire processes from model generation of the ceramic material to final selection and provides an integrated database on the properties of ceramic materials.

As such, the development period and costs for selecting the composition and physical property of the material having desired conditions may be reduced.

According to the embodiments of the present disclosure, the method of evaluating the physical property of a material based on a digital technique, which is capable of overcoming low efficiency of the material property evaluation method according to the related art and the limitations in manufacturing specimen, may be provided.

Also, by providing the method of evaluating the physical property of the material, costs and time duration taken to perform experiments on the new material and produce the new material.

While the disclosure has been particularly shown and described with reference to exemplary embodiments thereof, it will be understood by those of ordinary skill in the art that various changes in form and details may be made therein without departing from the spirit and scope as defined by the following claims. Therefore, the scope sought to be protected of the disclosure shall be defined by the appended claims.

The particular implementations shown and described herein are illustrative examples of the embodiments and are not intended to otherwise limit the scope of the embodiments in any way. Moreover, no item or component is essential to the practice of the inventive concept unless the element is specifically described as “essential” or “critical”.

The singular forms “a,” “an” and “the” in the specification of the embodiments, in particular, claims, may be intended to include the plural forms as well. Unless otherwise defined, the ranges defined herein is intended to include values within the range as individually applied and may be considered to be the same as individual values constituting the range in the detailed description. Finally, operations constituting methods may be performed in appropriate order unless explicitly described in terms of order or described to the contrary. Exemplary embodiments are not necessarily limited to the order of operations given in the description. The examples or exemplary terms (for example, etc.) used herein are to merely describe exemplary embodiments in detail are not intended to limit the embodiments unless defined by the following claims. Also, those of ordinary skill in the art will readily appreciate that many alternations, combinations and modifications, may be made according to design conditions and factors within the scope of the appended claims and their equivalents.

What is claimed is:

1. A method of evaluating hardness of a ceramic material by using computational simulation, the method comprising:
a first operation in which a crystal structure model reflecting a kind and amount of an element to be added to a material is generated;
a second operation in which a stabilized structure, in which the crystal structure model has the lowest energy, of the crystal structure model is selected;
a third operation in which a plurality of modified models having a series of strains with respect to the stabilized structure are generated;
a fourth operation in which elastic moduli about respective modified models are calculated from the strains and energy; and
a fifth operation in which a finite element analysis program simulating an indentation test on a crystal structure is modeled, and the elastic moduli are substituted into the finite element analysis program to extract physical property data about the crystal structure model.

2. The method of claim 1, wherein
the material is a ceramic material including a carbide.

3. The method of claim 1, further comprising
determining a synthesis possibility of the crystal structure model by calculating formation energy of the crystal structure model.

4. The method of claim 1, further comprising
determining a synthesis possibility of the crystal structure model by comparing the crystal structure model with competing phases.

5. The method of claim 1, wherein
the elastic modulus includes a bulk modulus and a shear modulus, or Young's modulus of the material.

6. The method of claim 1, wherein
the physical property data include hardness of the material.

7. A system for evaluating hardness of a ceramic material by using computational simulation, the system comprising:
a memory storing a program configured to calculate an elastic modulus of a material and extract physical property data of the material from the elastic modulus; and
a processor configured to generate a crystal structure model of the material, calculate the elastic modulus of the crystal structure model through the program stored in the memory, generate the physical property data, and determine suitability of the material based on the elastic modulus and the physical property data.
